(19) United States
(12) Patent Application Publication
(10) Pub. No.: US 2018/0196790 A1
(43) Pub. Date: Jul. 12, 2018

(54) SYSTEM FOR AND METHOD OF TRANSCEIVING DATA USING SYNCHRONIZATION-BASED ENCODING

(71) Applicant: Ulsan National Institute of Science and Technology, Ulsan (KR)

(72) Inventors: Kyunghan Lee, Ulsan (KR); Woo Seung Nam, Ulsan (KR)

(21) Appl. No.: 15/864,037

(22) Filed: Jan. 8, 2018

(30) Foreign Application Priority Data
Jan. 11, 2017 (KR) 10-2017-0004051

(51) Int. Cl. G06F 17/22; H03M 7/30; G06F 17/30

(52) U.S. Cl. CPC G06F 17/2211; G06F 17/30011; G06F 17/30672; H03M 7/30

(57) ABSTRACT

Provided are a system for and method of transceiving data using synchronization-based encoding. The method includes selecting at least one piece of data from among synchronized data and generating reference data and list data based on the selected data, combining a rear end of the reference data with a front end of target data and generating virtual data, extracting a result of encoding the target data from a result of encoding the virtual data and generating target compression data, and transmitting the list data and the target compression data.

### RELATED APPLICATION

This application claims the benefit of priority of Korean Patent Application No. 10-2017-0004051 filed Jan. 11, 2017, the contents of which are incorporated herein by reference in their entirety.

### FIELD AND BACKGROUND OF THE INVENTION

The present invention relates to a system for and method of transceiving data using synchronization-based encoding, and more particularly, to a system for and method of encoding transceiving target data based on already synchronized data and transceiving the encoded target data.

For the last decade, data storage services, such as Dropbox, OneDrive, and Google Drive, have emerged and been used by many users. By 2018, the number of users of cloud-storage is expected to be up to 2 billion.

Data storages provide a synchronization function and automatically synchronize data stored in a storage on a cloud and data stored on a user terminal even if a user does not recognize the synchronization of the data. Data synchronization is not new but has frequently been used in conventional distributed systems.

The data synchronization is not just limited to a data storage but may be applied in fields, such as data communication between users, sensor data synchronization between sensors, and synchronization of research data between laboratories.

When generalized to a data transmission situation between two systems that have some of the same data in a data transmission service, the above-described technique may be surprisingly extended. In actual data transmission, there are many situations where bandwidths are limited. In this case, since transmission costs are very large, it is necessary to provide a technique of reducing a size of transmission data by using synchronization data between a receiving end and a transmitting end.

### Prior-Art Document

(Patent Document 1)

Korean Patent Publication No. 2010-0050072

### SUMMARY OF THE INVENTION

The present invention is directed to a system for and method of encoding transmission target data based on already synchronized data, transmitting the encoded target data, receiving the encoded target data, and decoding the encoded target data.

It should be noted that objects of the present invention are not limited to the above-described objects, and other objects of the present invention will be apparent to those skilled in the art from the following descriptions.

According to an aspect of the present invention, there is provided a method of transmitting data, the method including selecting at least one piece of data from among synchronized data and generating reference data and list data based on the selected data, combining a rear end of the reference data with a front end of target data and generating virtual data, extracting a result of encoding the target data from a result of encoding the virtual data and generating target compression data, and transmitting the list data and the target compression data.

### BRIEF DESCRIPTION OF THE SEVERAL VIEWS OF THE DRAWINGS

The above and other objects, features and advantages of the present invention will become more apparent to those of ordinary skill in the art by describing in detail exemplary embodiments thereof with reference to the accompanying drawings, in which:

FIG. 1 is a diagram illustrating configuration of a data transceiving system according to an exemplary embodiment of the present invention;

FIG. 2 is a diagram illustrating configuration of a data transmission device according to an exemplary embodiment of the present invention;

FIG. 3 is a diagram illustrating configuration of a data receiving device according to an exemplary embodiment of the present invention;

FIG. 4 is a diagram illustrating an example of conventional data encoding;

FIG. 5 is a diagram illustrating synchronization-based encoding according to an exemplary embodiment of the present invention;

FIG. 6 is a flowchart of a method of transmitting data using synchronization-based encoding according to an exemplary embodiment of the present invention;

FIG. 7 is a flowchart of a method of receiving data using synchronization-based encoding according to an exemplary embodiment of the present invention;

FIG. 8 is a diagram of a method of transceiving data using synchronization-based encoding according to an exemplary embodiment of the present invention;

FIG. 9 shows experimental results obtained by comparing compression rates of data storages by using synchronization-based encoding, according to an exemplary embodiment of the present invention; and

FIG. 10 shows experimental results obtained by comparing compression rates of web pages when websites are visited by using synchronization-based encoding, according to an exemplary embodiment of the present invention.

### DESCRIPTION OF SPECIFIC EMBODIMENTS OF THE INVENTION

Various exemplary embodiments will now be described more fully with reference to the accompanying drawings in which some exemplary embodiments are shown. Advantages and features of the present invention and methods of achieving the same will be clearly understood with reference to the following detailed examples. However, the present invention is not limited to the examples to be disclosed below, but may be implemented in various different forms. The examples are provided in order to fully explain the present invention and fully explain the scope of the present invention for those skilled in the art. The scope of the present invention is not defined by the appended claims. Like numbers refer to like elements throughout the specification.

Unless defined otherwise, all terms used herein including technical or scientific terms have the same meanings as those generally understood by those of ordinary skill in the art to which the present inventive concept may pertain. The terms as those defined in generally used dictionaries are construed to have meanings matching that in the context of related technology and, unless clearly defined otherwise, are not construed to be ideally or excessively formal.

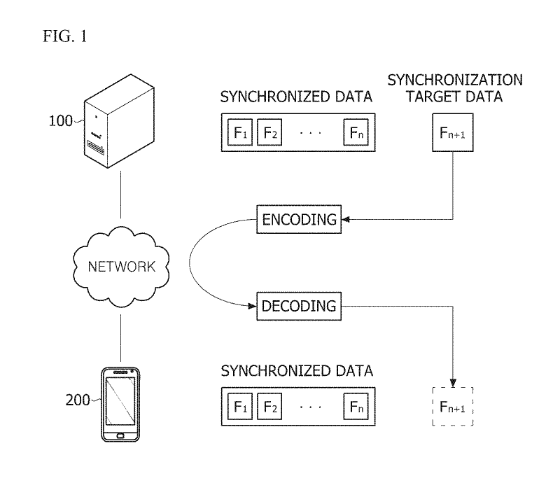

FIG. 1 is a diagram illustrating configuration of a data transceiving system according to an exemplary embodiment of the present invention. The configuration of the data transceiving system according to the exemplary embodiment of the present invention will be described in detail with reference to FIG. 1.

The data transceiving system according to the exemplary embodiment of the present invention may include a data transmission device 100 and a data receiving device 200. The data transmission device 100 and the data receiving device 200 may be any devices which share the same data. Unless there are other definitions below, the same data existing between the data transmission device 100 and the data receiving device 200 may be referred to as synchronized data.

For example, the data transmission device 100 may be a data storage server, and the data receiving device 200 may be a personal computer (PC), a smartphone, a tablet, a smart device, or a notebook, which may be connected to the data storage server.

In another example, the data transmission device 100 may be a web server, and the data receiving device 200 may be any devices by which a web browser is executed.

In yet another example, the data transmission device 100 and the data receiving device 200 may be connected to each other by peer-to-peer (P2P) and each may be any one of a data storage server, a personal computer (PC), a smartphone, a tablet, a smart device, and a notebook.

The data transmission device 100 may include data synchronized with the data receiving device 200. Hereinafter, it is assumed for brevity that the synchronized data includes data F₁ to Fₙ. The data transmission device 100 may include synchronization target data Fₙ₊₁, which is a newly generated data or newly input data. Since the synchronization target data Fₙ₊₁ is present only in the data transmission device 100 but not present in the data receiving device 200, the data transmission device 100 may need to transmit the synchronization target data Fₙ₊₁ to the data receiving device 200 and synchronize the synchronization target data Fₙ₊₁ with the data receiving device 200.

When transmitting the synchronization target data Fₙ₊₁, the data transmission device 100 may compress the synchronization target data Fₙ₊₁ to reduce a size of data to be transmitted. The compression of the synchronization target data Fₙ₊₁ may include encoding the data to be transmitted according to a specific algorithm. A conventional compression algorithm may encode the data to be transmitted alone. The data transmission device 100 according to the exemplary embodiment of the present invention may encode the synchronization target data Fₙ₊₁ by using the synchronized data F₁ to Fₙ, thereby elevating compression efficiency and further reducing the size of data to be transmitted.

The data receiving device 200 may receive the encoded data. The data receiving device 200 may decode the received data according to the algorithm and restore the synchronization target data Fₙ₊₁. The data receiving device 200 may use the synchronized data F₁ to Fₙ during the decoding process. The data receiving device 200 may store the restored synchronization target data Fₙ₊₁ to complete the synchronization process.

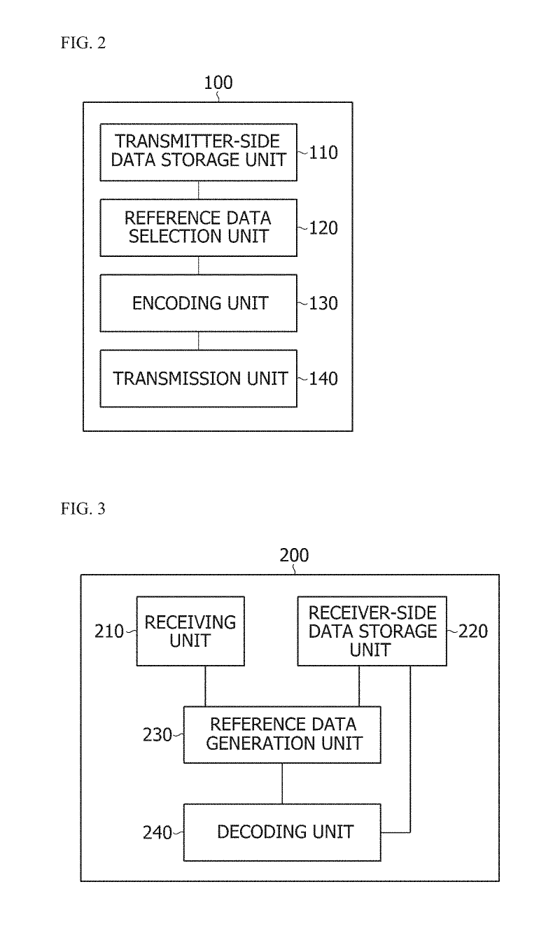

FIG. 2 is a diagram illustrating configuration of a data transmission device 100 according to an exemplary embodiment of the present invention. The configuration of the data transmission device 100 according to the exemplary embodiment of the present invention will be described in detail with reference to FIG. 2.

The data transmission device 100 may include a transmitter-side data storage unit 110, a reference data selection unit 120, an encoding unit 130, and a transmission unit 140.

Synchronized data may be stored in the transmitter-side data storage unit 110. Although the synchronized data may be divided according to a unique discrimination identification (ID) or discrimination address and stored in the transmitter-side data storage unit 110, but this is merely an example, and the present invention is not limited thereto. The transmitter-side data storage unit 110 may include the synchronized data and list information for discriminating the synchronized data.

The reference data selection unit 120 may select data for encoding target data, which is a transmission target in the transmitter-side data storage unit 110, and generate list data and reference data based on the selected data. The list data may include the list information of the selected data. The reference data may be one data unit obtained by combining the selected data. The list information may be a file path or file address of the selected data. The reference data may be data obtained by continuously connecting the selected data at a bit stream level.

For example, when the selected data is a plurality of files, the list data may include a file path of each piece of the selected data.

In another example, when the selected data is a plurality of web pages, the list data may include path information indicating a hypertext markup language (HTML), a cascading style sheet (CSS) file, and javascript of a cached web page related to the selected data or position information in a web page. The plurality of selected web pages may be information about previously visited web pages stored in both the data transmission device 100 and the data receiving device 200, and the visited web pages may be stored as cache information. Further, the web pages may include not only HTML syntax but also a plurality of script syntaxes, and the selected data may be components included in the web pages. In this case, the list data may include path information about the web pages and information about positions of the components in the web pages.

The reference data selection unit 120 may calculate a similarity between each piece of data stored in the transmitter-side data storage unit 110 and the target data. The reference data selection unit 120 may select a predetermined number of pieces of data in the order of calculated similarities. The reference data selection unit 120 may arrange the selected data in ascending order of the similarities, generate list data about the selected data in the arranged order, and combine respective pieces of the selected data in the arranged order to generate reference data.

Alternatively, the reference data selection unit 120 may arbitrarily select a predetermined number of pieces of data from respective pieces of data stored in the transmitter-side data storage unit 110. The reference data selection unit 120 may arbitrarily arrange the selected data, generate list data in the arranged order, and sequentially combine the selected data in the arranged order, and generate the reference data.

The encoding unit 130 may generate virtual data in which a rear end of the selected reference data is combined with a front end of the target data. The encoding unit 130 may generate target compression data, which is an encoding result of the target data, based on a result of encoding the virtual data according to a Lumpel-Ziv (LZ)-based data encoding algorithm, such as Lempel-Ziv-Markov chain algorithm (LZMA), LZ77, and LZ78, or a PAQ-based data encoding algorithm. In the exemplary embodiment of the present invention, an example in which an LZMA-based encoding method is applied to the encoding unit 130 will be described. However, the encoding unit 130 may perform an encoding process without depending on a specific compression technique by using a compression technique having a structure capable of efficiently using inter-data correlation between synchronized data and data to be transmitted.

In the exemplary embodiment of the present invention, an LZMA may be a lossless compression algorithm used for data compression. Since the LZMA is a known technique, a detailed description thereof will be omitted. The reference data may be combined with a front end of the target data so that the reference data may be included in a dictionary or window of the target data when an encoding process is performed according to the LZMA. In a conventional LZMA, when the target data is encoded, since there is no data to be referred to at a first portion of the target data, an initial compression rate may be inevitably low. To solve the problem, according to the exemplary embodiment of the present invention, reference data having a high similarity to the target data may be located at the front end of the target data to improve compression efficiency.

The encoding unit 13 may generate virtual compression data, which is a result of encoding the virtual data according to the LZMA. The encoding unit 130 may store only a result of encoding a portion of the target data of the virtual data according to the LZMA, during the process of encoding the virtual data according to the LZMA and generate the target compression data.

For example, when the virtual data is encoded according to the LZMA, a start point may be located at a front portion of the target data included in the virtual data, and a window may be set to include reference data. Thereafter, the encoding process may be performed, and a result of encoding the target data according to the LZMA may be stored to generate the target compression data.

In another example, to encode the virtual data according to the LZMA, while sequentially performing the encoding process from a first portion of the virtual data, when the encoding of the front portion of the target data included in the virtual data begins, only subsequent encoding results may be stored to generate the target compression data.

The transmission unit 140 may transmit the list data and the target compression data. In addition, the transmission unit 140 may compress the list data and transmit the compressed list data.

FIG. 3 is a diagram illustrating configuration of a data receiving device 200 according to an exemplary embodiment of the present invention. The configuration of the data receiving device 200 according to the exemplary embodiment of the present invention will be described in detail with reference to FIG. 3.

The data receiving device 200 may include a receiving unit 210, a receiver-side data storage unit 220, a reference data generation unit 230, and a decoding unit 240.

Synchronized data may be stored in the receiver-side data storage unit 220. List information about the synchronized data may be stored in the receiver-side data storage unit 220. The synchronized data and the list information may be the same as those stored in the transmitter-side data storage unit 110 of the data transmission device 100.

The receiving unit 210 may receive list data about target compression data and reference data, which are encoded based on the synchronized data according to an LZMA.

The reference data generation unit 230 may inquire data corresponding to list information included in the list data from the receiver-side data storage unit 220 and generate reference data based on inquired data. The reference data generation unit 230 may inquire the data corresponding to the list information included in the list data in an order in which the list information is included in the list data, from the receiver-side data storage unit 220, combine the data in an inquired order, and generate the reference data.

The decoding unit 240 may encode the generated reference data according to the LZMA and generate reference compression data. The decoding unit 240 may combine a rear end of the generated reference compression data with a front end of the received target compression data and generate virtual compression data. The decoding unit 240 may decode the virtual compression data according to the LZMA and generate virtual data. The decoding unit 240 may generate the target data based on the virtual data.

For example, the decoding unit 240 may extract a portion excluding the reference data from the virtual data and generate the target data. Since the virtual data is generated by combining the reference data with the front end of the target data, by deleting a portion of a front portion of the virtual data, which is consistent with the reference data, the remaining portion of the virtual data may be extracted as the target data.

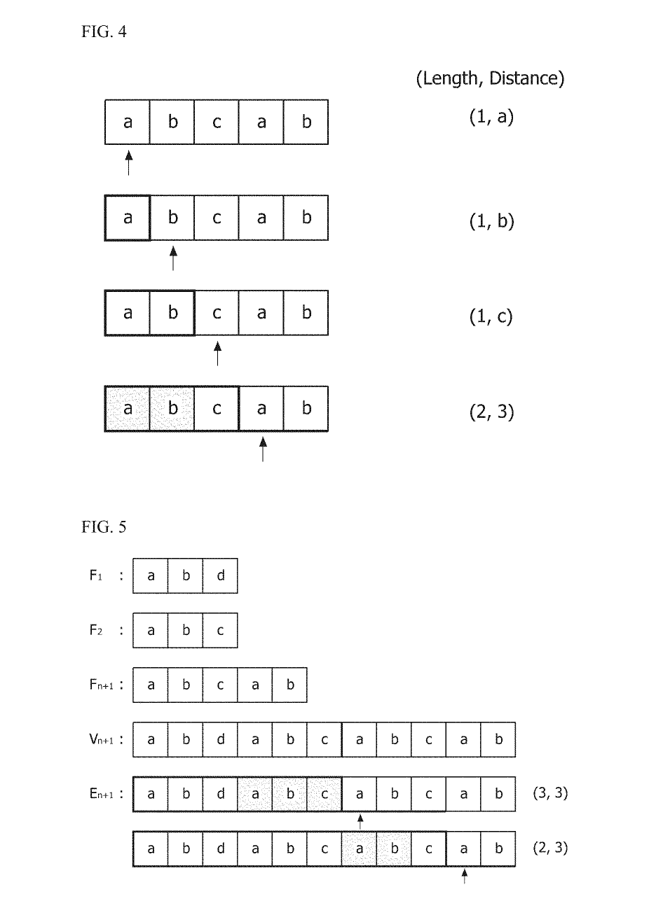

FIG. 4 is a diagram illustrating an example of conventional data encoding according to an LZMA. The conventional data encoding operation according to the LZMA will be exemplarily described with reference to FIG. 4.

For brevity, it is assumed that target data to be transmitted is a letter stream of ‘abcab’, and an encoding result of the LZMA is output as a combination (length, distance).

When a pointer of the LZMA points at ‘a’, which is a front portion of the target data, an encoding process may begin. ‘a’ may be directly output because there is no reference data in front of ‘a’. Thus, although a length is 1 and a distance is 0, when the distance is 0, a letter to be output may be intactly output to a distance input portion. Accordingly, an encoding result may be (1, a).

Next, the pointer may be moved sideward by as much as 1 to point at ‘b’. A front portion of the pointer may be a window. In this case, the window may be ‘a’. Since there is no letter corresponding to ‘b’ in the window, ‘b’ may be intactly output. Accordingly, an encoding result may be (1, b).

Next, the pointer may be moved sideward by as much as 1 to point at ‘c’. In this case, the window may be ‘ab’. Since there is also no letter corresponding to ‘c’ in the window, ‘c’ may be intactly output. Accordingly, an encoding result may be (1, c).

Next, the pointer may be moved sideward by as much as 1 to point at ‘a’. In this case, the window may be ‘abc’. ‘ab’ that starts at the pointer may be included in the window. A distance from ‘ab’ to ‘abc’ in the window may be 3, and a length may be 2. Accordingly, an encoding result may be (2, 3).

Finally, results of encoding ‘abcab’ according to the LZMA may be (1, a), (1, b), (1, c), and (2, 3). The encoding results may be exemplary results obtained by using the LZMA. A result format may depend on a method of implementing an LZMA.

FIG. 5 is a diagram illustrating a synchronization-based encoding process according to an exemplary embodiment of the present invention. The synchronization-based encoding process according to the exemplary embodiment of the present invention will be described in detail with reference to FIG. 5.

According to an exemplary embodiment of the present invention, it is assumed that target data Fₙ₊₁ to be transmitted is ‘abcab’. It is assumed that two pieces of data having high similarities to the data Fₙ₊₁, which are selected from the synchronized data F₁ to Fₙ, are F₁ and F₂. Assuming that F₁ is ‘abd’ and F₂ is ‘abc’, data F₂ may have a higher similarity than data F₁.

Accordingly, virtual data Vₙ₊₁ may be generated by combining data F₁, F₂, and Fₙ₊₁ in sequential order.

When the virtual data Vₙ₊₁ is encoded according to the LZMA, only an encoding result for the data Fₙ₊₁ may be extracted as follows.

When the pointer of the LZMA points at ‘a’ that is a first letter of the data Fₙ₊₁, the window may be ‘abdabc’. In this case, ‘abc’ that starts at the pointer of the LZMA may be included in the window. A distance may be 3, and a length may be 3. Accordingly, an encoding result may be (3, 3).

Next, the pointer may be moved sideward by as much as 3 to point at ‘a’. In this case, the window may be ‘abdabcabc’. ‘ab’ that starts at the pointer may be included in the window. A distance may be 3, and a length may be 2. Accordingly, an encoding result may be (2, 3).

Finally, target compression data, which are results of encoding ‘abcab’ that is the target data Fₙ₊, may be (3, 3) and (2, 3).

Referring back to FIG. 4, the results of encoding abcab according to the conventional LZMA may be (1, a), (1, b), (1, c), and (2, 3). However, results of encoding according to the exemplary embodiment of the present invention may be (3, 3) and (2, 3), and it can be confirmed that the number of pairs (length, distance) is reduced more than in the conventional case.

A compression rate of the LZMA may increase as more data is matched in the window. In a conventional LZMA, since target data is encoded with reference to only the target data itself, a replacement probability may be low due to a small window during an initial encoding process. Since part of initially synchronized data is included in the window, a replacement probability of an encoding process according to the exemplary embodiment of the present invention may be increased. For example, since there is a probability that a data stream unique to only the target data exists in the window including the part of the data synchronized during the initial encoding process, a replacement probability of part that cannot be matched when the target data is conventionally encoded with reference to only the target data, may also increase. Accordingly, the overall compression rate may be further improved.

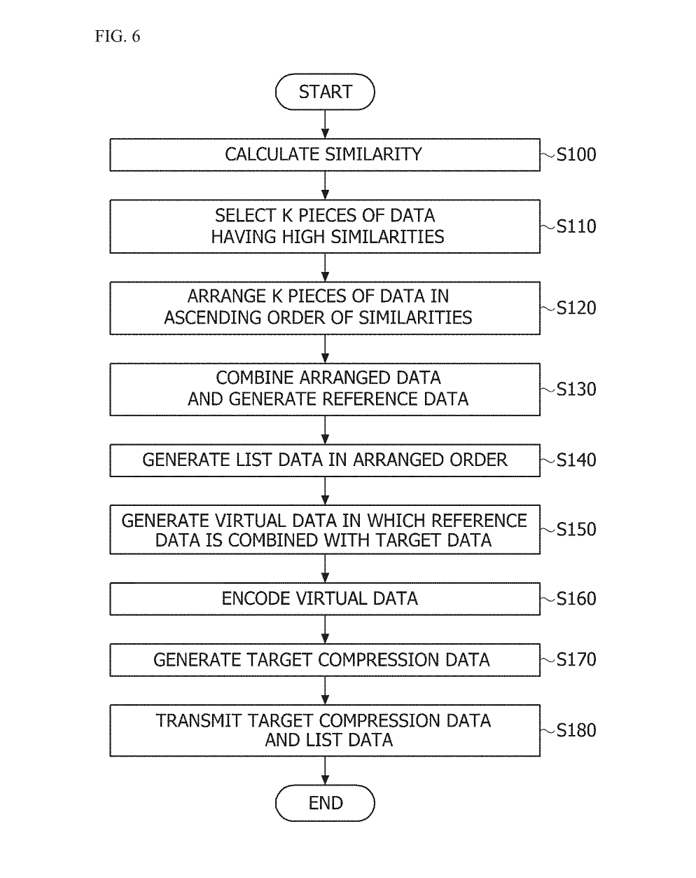

FIG. 6 is a flowchart of a method of transmitting data using synchronization-based encoding according to an exemplary embodiment of the present invention. The method of transmitting data using synchronization-based encoding will be described in detail with reference to FIG. 6.

Similarities between target data Fₙ₊₁ to be transmitted and synchronized data F₁ to Fₙ may be calculated (S100). The similarities may be calculated by using a cosine similarity method. In the cosine similarity method, a similarity may be judged to be higher as the number of types of matching words between two documents to be compared increases. Although the cosine similarity method is described as an example in the exemplary embodiment of the present invention, a similarity calculation method is not limited thereto. Various methods of calculating similarities may be applied by using a document similarity measurement method of comparing different types of documents, such as a string metric method and a radial basis function (RBF) kernel method.

For example, cosine similarities between documents A and T may be calculated as follows:

$$sin ( A , T ) {=}^{Δ} \frac{{Σ}_{i ∈ S ( T )} f ( {t}_{i}^{A} ) f ( {t}_{i}^{T} )}{\sqrt{{Σ}_{i ∈ S ( T )} {f ( {t}_{i}^{A} )}^{2}} \sqrt{{Σ}_{i ∈ S ( T )} {f ( {t}_{i}^{T} )}^{2}}}$$

f(tᵢ^{A}) may be a function to which a weight is applied to tᵢ^{A} when tᵢ^{A} is the number of occurrences of a word ‘i’ in the document A. For example, when the word ‘1’ occurs at least once in the document A, f(tᵢ^{A})=1; and when there is no word ‘1’ in the document A, f(tᵢ^{A})=0. S(T) may be a set of discriminable words present in the document T.

Since the cosine similarity method is a known technique that may be used by one skilled in the art without any difficulties, a detailed description thereof will be omitted.

According to an exemplary embodiment of the present invention, similarities between target data and the synchronized data may be calculated by using a cosine similarity method.

Based on the calculated similarities, k pieces of data having high similarities may be selected (S110). Here, k may be a predetermined number. The synchronized data may be arranged based on the calculated similarities, and the k pieces of data having the high similarities may be selected.

The k pieces of selected data may be arranged in ascending order of similarities (S120). The ascending order may refer to arranging data from a lowest similarity to a highest one. In other exemplary embodiments, although random arrangement of data or arrangement of data in descending order may be used, the present invention is not limited thereto. The k pieces of selected data may be arranged in the ascending order of similarities in order to reduce a matching distance with letters included in the target data when the reference data is combined with the target data.

The arranged pieces of data may be combined to generate reference data (S130). The k pieces of selected data, which may be arranged in the ascending order of similarities, may be sequentially combined in a bit stream level to generate one piece of reference data.

List information about the arranged data may be collected in the arranged order to generate list data (S140). The list information may be a file path, a file address, or a uniform resource locator (URL) about the data. The list information may be collected in the arranged order and stored to generate the list data.

The reference data may be combined with the target data to generate virtual data (S150). To improve compression efficiency of encoding, a rear end of the reference data may be combined with a front end of the target data to generate the virtual data.

The virtual data may be encoded according to a LZMA (S160). The virtual data may be encoded according to the LZMA to generate virtual compression data.

Only a portion about the target data may be extracted from the virtual compression data to generate target compression data (S170). During the process of encoding the virtual data, only a result of encoding the portion of the target data included in the virtual data according to the LZMA may be stored to generate the target compression data. For example, when the portion of the target data included in the virtual data is encoded according to the LZMA, a start point may be located in a first portion of the target data included in the virtual data, a window may be designated as a portion of the reference data included in the virtual data, and the encoding process may be performed to store the result of encoding the target data according to the LZMA.

The target compression data and the list data may be transmitted (S180). The list data may be transmitted as an original document or transmitted by further encoding the list data.

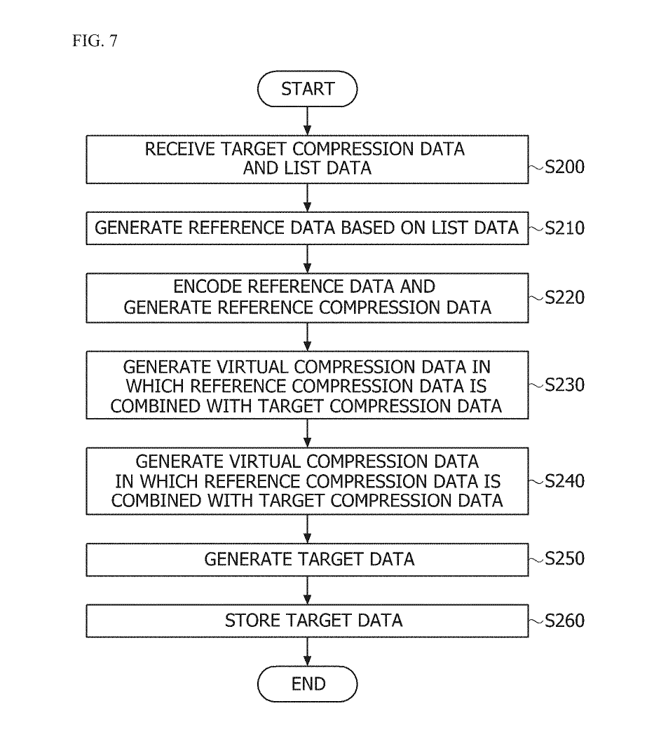

FIG. 7 is a flowchart of a method of receiving data using synchronization-based encoding according to an exemplary embodiment of the present invention. The method of receiving data using synchronization-based encoding according to the exemplary embodiment of the present invention will be described in detail with reference to FIG. 7.

Target compression data and list data may be received (S200). When the list data is encoded, the list data may be replaced by decoded list data.

Reference data may be generated based on the list data (S210). Synchronized data corresponding to list information included in the list data may be inquired in the order of the list information, and the inquired data may be combined in the order of the list information to generate the reference data.

The reference data may be encoded to generate reference compression data (S220). Reference compression data may be generated as a result of encoding the reference data according to the LZMA.

The reference compression data may be combined with the target compression data to generate virtual compression data (S230). A rear end of the reference compression data may be combined with a front end of the target compression data to generate the virtual compression data.

The virtual compression data may be decoded according to the LZAM to generate virtual data (S240).

Target data may be generated based on a decoding result of the virtual data (S250).

During the process of decoding the virtual compression data, the target data may be generated by storing only a result obtained from a time point when a start point of the target compression data included in the virtual compression data is decoded.

The generated target data may be stored together in a location in which synchronized data is stored (S260). The generated target data may be stored in the receiver-side data storage unit 220 of the data receiving device.

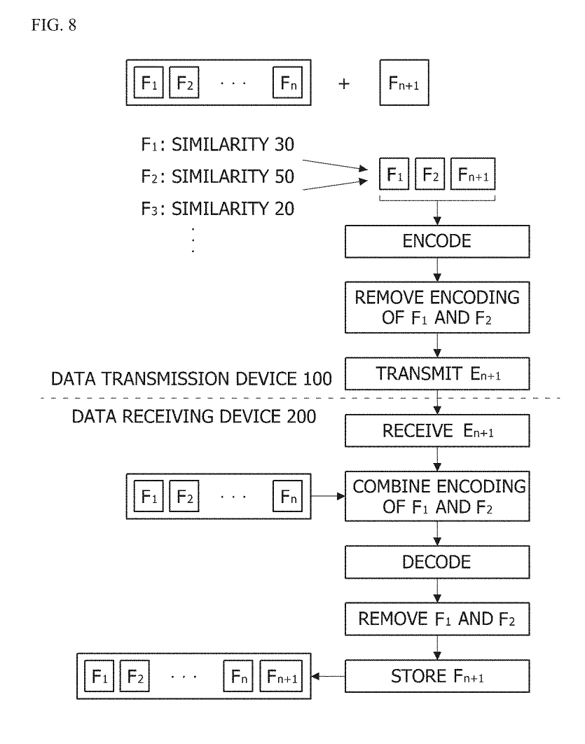

FIG. 8 is a diagram of a method of transceiving data using synchronization-based encoding according to an exemplary embodiment of the present invention. The method of transceiving data using the synchronization-based encoding according to the exemplary embodiment of the present invention will be generally described with reference to FIG. 8.

A data receiving device 200 may include already synchronized data F₁ to Fₙ. The synchronized data may be a synchronized file or a previously visited web page.

To synchronize new target data Fₙ₊₁ with the data receiving device 200, the data receiving device 200 may encode the target data Fₙ₊₁ and generate target compression data Eₙ₊₁.

To generate the target compression data Eₙ₊₁, similarities between the synchronized data and the target data may be calculated. Although the present embodiment describes an example in which the similarities are calculated using a cosine similarity method, the present invention is not limited thereto, and other methods of calculating similarities may be used.

Several synchronized data (e.g., synchronized data F₁ and F₂) having high calculated similarities may be selected, list data about the selected synchronized data F₁ and F₂ may be generated, and reference data in which the selected synchronized data F₁ and F₂ are combined may be generated. The reference data may be combined with a front end of target data Fₙ₊₁ to generate virtual data, and the generated virtual data may be encoded.

During the process of encoding the virtual data, only a result of encoding a portion of target data included in the virtual data may be stored to thereby generate target compression data Eₙ₊₁.

In the exemplary embodiment of the present invention, by selecting synchronized data having high similarities, a probability of matching with data included in target data may be increased during the encoding process. Further, by combining the selected data with the front end of the target data, a size of a window may be increased during the encoding process according to the LZMA so that a compression rate can be elevated.

The data transmission device 100 may transmit list data of target compression data En+1 and reference data to the data receiving device 200.

The data receiving device 200 may collect data F₁ and F₂ corresponding to list information included in the list data, from among synchronized data included in the data receiving device 200, based on the list data, and generate reference data.

The data receiving device 200 may encode the reference data according to the LZMA and generate reference compression data. The data receiving device 200 may combine the reference compression data with a front end of the target compression data and generate virtual compression data.

The data receiving device 200 may decode the virtual compression data according to the LZMA and generate virtual data. During the process of decoding the virtual compression data, the data receiving device 200 may store only a result of decoding a portion of the target compression data included in the virtual compression data and generate the virtual data.

The data receiving device 200 may store the target data Fₙ₊₁ in the receiver-side data storage unit 220 in which the synchronized data is stored, and complete the synchronization process.

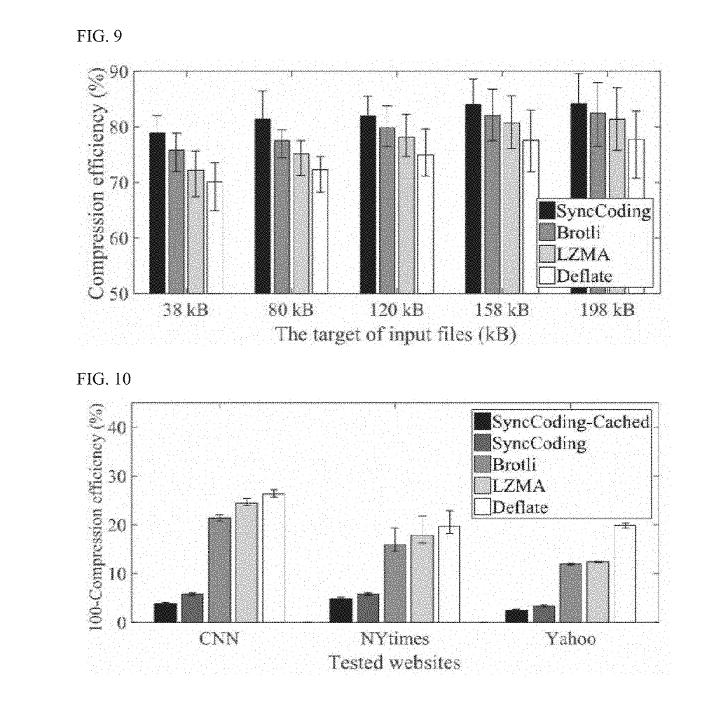

FIG. 9 shows experimental results obtained by comparing compression rates of data storages by using synchronization-based encoding, according to an exemplary embodiment of the present invention.

Referring to FIG. 9, the synchronization-based encoding according to an exemplary embodiment may be denoted by SyncCoding. When comparing with Broth, LZMA, and Deflate that are conventional compression methods, SyncCoding shows the highest compression rate in all file sizes tested.

FIG. 10 shows experimental results obtained by comparing compression rates of web pages when websites are visited by using synchronization-based encoding, according to an exemplary embodiment of the present invention.

Referring to FIG. 10, synchronization-based encoding according to an exemplary embodiment of the present invention may be denoted by SyncCoding-Cached using cached-data of cache web data and SyncCoding using no cached-data. When comparing with Bortli, LZMA, and Defalte that are the conventional compression methods, SyncCoding shows the highest compression rate.

A term ‘˜ unit’ used in the present embodiment may refer to a software component or a hardware component, such as a field-programmable gate array (FPGA) or an application specific integrated circuit (ASIC), and serve specific functions. However, the term ‘˜ unit’ is not construed as being limited to software or hardware. The term ‘˜ unit’ may be configured to be in an addressable storage medium or reproduce at least one processor. Thus, in one example, the term ‘˜ unit’ may include components such as software components, object-oriented software components, class components, and task components, processes, functions, attributes, procedures, subroutines, segments of a program code, drivers, firmware, microcodes, circuits, data, databases, data structures, tables, arrays, and variables. Functions provided in the components and the ‘˜ units’ may be combined to configure a smaller number of components and ‘˜ units’ or further separated into additional components and ‘˜ units’. In addition, the components and the ‘˜ units’ may be implemented to reproduce at least one CPU in a device or a secure multimedia card (MMC).

According to the present invention as described above, synchronized data can be utilized as reference data for an encoding process. Thus, efficiency of a conventional compression algorithm can be enhanced to obtain a relatively high compression rate. As a result, a bandwidth required for the transmission of target data can be reduced.

In addition, the present invention has an effect in that the entire or partial portion of the target data that is consistent with the reference data can be selectively used to a fixed size or a variable size during the encoding process.

Furthermore, according to the present invention as described above, the synchronized data may be equally applied between a transmitter side and a receiver side. Thus, the synchronized data may be applied not only to transmission of files between a cloud file server and a client but also to transmission of web pages between a web server and a web browser, thereby increasing a web page loading speed.

Although the embodiments of the present invention have been described with reference to the accompanying drawings, it will be apparent to those skilled in the art that various modifications can be made to the above-described exemplary embodiments of the present invention without departing from the spirit or scope of the invention. Thus, it is intended that the present invention covers all such modifications provided they come within the scope of the appended claims and their equivalents.

What is claimed is:

1. A method of encoding target data and transmitting the encoded target data, the method comprising:
selecting at least one piece of data from among synchronized data and generating reference data and list data based on the selected data;
combining a rear end of the reference data with a front end of the target data and generating virtual data;
extracting a result of encoding the target data from a result of encoding the virtual data and generating target compression data; and
transmitting the list data and the target compression data.

2. The method of claim 1, wherein the synchronized data comprises a synchronized file or a previously visited web page.

3. The method of claim 1, wherein the generating of the reference data comprises:
calculating similarities between data included in the synchronized data and the target data; and
generating the reference data based on the synchronized data and the calculated similarities.

4. The method of claim 3, wherein the generating of the reference data comprises:
selecting a predetermined number of pieces of data in an order of the calculated similarities from among the synchronized data; and
combining the selected pieces of data and generating the reference data.

5. The method of claim 3, wherein the generating of the reference data comprises:
arranging respective pieces of data included in the selected data from a low similarity to a highest similarity; and
combining the arranged pieces of data in an arranged order to generate unified reference data.

6. The method of claim 5, wherein the generating of the list data comprises generating list data in which reference information about each piece of data included in the selected data is included in the arranged order.

7. The method of claim 1, wherein the generating of the target compression data comprises generating the target compression data in which only a result of encoding a portion of the target data included in the virtual data is stored when the virtual data is encoded.

8. The method of claim 7, wherein the generating of the target compression data comprises:
locating an encoding start point at a first portion of the target data included in the virtual data;
setting a window to include reference data and performing the encoding process; and
storing results of encoding the target data and generating the target compression data.

9. The method of claim 7, wherein the generating of the target compression data comprises generating the target compression data by storing only encoding results subsequent to the encoding of a first portion of the target data included in the virtual data when the encoding of the first portion of the target data included in the virtual data begins while sequentially performing the encoding process from a first portion of the virtual data.

10. A method of receiving encoded data, the method comprising:
receiving list data and target compression data;
generating reference data including data corresponding to the list data from among synchronized data;
encoding the generated reference data and generating reference compression data;
combining the generated reference compression data with a front end of the target compression data and generating virtual compression data;
decoding the virtual compression data and generating virtual data; and
storing only a result of decoding of a portion of the target compression data included in the virtual data during the decoding of the virtual compression data and generating target data.

11. The method of claim 10, wherein the generating of the reference data comprises:
inquiring data corresponding to list information included in the list data in an order in which respective pieces of the list information are included in the list data; and
combining the inquired data in the order in which the respective pieces of the list information are included in the list data to generate the reference data.

12. A data transmission device configured to encode target data and transmit the encoded target data, the device comprising:
a transmitter-side data storage unit configured to store synchronized data therein;
a reference data selection unit configured to select data for encoding the target data in the transmitter-side data storage unit and generate list data and reference data based on the selected data;
an encoding unit configured to generate virtual data in which a rear end of the selected reference data is combined with a front end of the target data, and generate target compression data based on a result of encoding the virtual data, wherein the target compression data is a result of encoding the target data; and
a transmission unit configured to transmit the list data and the target compression data.

13. The data transmission device of claim 12, wherein the reference data selection unit calculates similarities between data included in the synchronized data and the target data and generate the reference data based on the synchronized data and the calculated similarities.

14. The data transmission device of claim 13, wherein the reference data selection unit selects a predetermined number of data in an order of the calculated similarities from among the synchronized data, combines the selected data, and generates the reference data.

15. The data transmission device of claim 13, wherein the reference data selection unit arranges respective pieces of data included in the selected data from a lowest similarity to a highest similarity, combines the arranged pieces of data in an arranged order, and generates unified reference data.

16. The data transmission device of claim 15, wherein the reference data selection unit enumerates reference information about respective pieces of data included in the selected data in the arranged order and generates list data.

17. The data transmission device of claim 12, wherein the encoding unit stores only a result of encoding a portion of the target data included in the virtual data according to a Lempel-Ziv-Markov chain algorithm (LZMA) during the encoding of the virtual data to generate the target compression data.

18. The data transmission device of claim 17, wherein when the virtual data is encoded according to the LZMA, the encoding unit locates an encoding start point at a front portion of the target data included in the virtual data, sets a window to include reference data, perform the encoding, and storing a result of encoding the target data to generate the target compression data.

19. The data transmission device of claim 17, wherein the encoding unit generates the target compression data by storing only encoding results subsequent to the encoding of a front portion of the target data included in the virtual data when the encoding of the front portion of the target data included in the virtual data begins while sequentially performing the encoding process from a first portion of the virtual data.

20. The data transmission device of claim 12, wherein the reference data is data obtained by continuously connecting the selected data at a bit stream level.
